(19) United States
(12) Patent Application Publication
(10) Pub. No.: US 2024/0230951 A1
(43) Pub. Date: Jul. 11, 2024

(54) DEVICES INCLUDING AN OPTICAL METASTRUCTURE, AND METHODS FOR DESIGNING METASTRUCTURES

(71) Applicant: NIL Technology ApS, Kongens Lyngby (DK)

(72) Inventors: Yuriy Elesin, Copenhagen (DK); Joachim Secher, Copenhagen (DK); Villads Egede Johansen, Copenhagen (DK)

(21) Appl. No.: 18/286,006

(22) PCT Filed: Apr. 6, 2022
(86) PCT No.: PCT/EP2022/059144

§ 371 Date: Oct. 6, 2023

Related U.S. Application Data
(60) Provisional application No. 63/173,068, filed on Apr. 9, 2021.

(51) Int. Cl. G02B 1/00; B82Y 20/00; G02B 3/00; H01L 31/0232

(52) U.S. Cl. CPC G02B 1/002; B82Y 20/00; G02B 3/0056; H01L 31/02325; G02B 2207/101

(57) ABSTRACT

An optical metastructure like a metalens is composed of unit cells, each of which has a respective unit cell design defined by a shape and area of meta-atoms for that unit cell, and by an arrangement of the meta-atoms within that unit cell. A first region of the metastructure comprises a plurality of adjacent unit cells that includes a subset of unit cells. The respective unit cell design for each of one or more of the plurality of unit cells that is in the first region, but that is not in the subset, is a respective interpolated unit cell design that is based on the respective unit cell designs of the unit cells in the subset. In case of a metalens, the lens is divided in annular regions for particular incident angles, an initial unit cell structure for an inner and an outer unit cell within the annular region is determined and optimised; the design of the unit cells located between the inner and outer unit cells is interpolated from the initial design.

### FIELD OF THE DISCLOSURE

The present disclosure relates to devices that include an optical metastructure.

### BACKGROUND

Advanced optical elements may include a metasurface, which refers to a surface with distributed small structures (e.g., meta-atoms) arranged to interact with light in a particular manner. For example, a metasurface, which also may be referred to as a metastructure, can be a surface with a distributed array of nanostructures. The nanostructures may, individually or collectively, interact with light waves. For example, the nanostructures or other meta-atoms may change a local amplitude, a local phase, or both, of an incoming light wave.

When meta-atoms (e.g., nanostructures) of a metasurface are in a particular arrangement, the metasurface may act as an optical element such as a lens, lens array, beam splitter, diffuser, polarizer, bandpass filter, or other optical element. In some instances, metasurfaces may perform optical functions that are traditionally performed by refractive and/or diffractive optical elements. The meta-atoms may be arranged, in some cases, in a pattern so that the metastructure functions, for example, as a lens, grating coupler or other optical element. In other instances, the meta-atoms need not be arranged in a pattern, and the metastructure can function, for example, as a fanout grating, diffuser or other optical element. In some implementations, the metasurfaces may perform other functions, including polarization control, negative refractive index transmission, beam deflection, vortex generation, polarization conversion, optical filtering, and plasmonic optical functions.

### SUMMARY

The present disclosure describes techniques for designing an optical metastructure that provides a specified optical function.

In one aspect, for example, a method can include determining a phase function for a metastructure design to produce a particular optical effect for a specified operational wavelength. The method further can include performing a phase wrapping operation with respect to unit cells of the metastructure design such that a resulting radial dimension of each unit cell falls within a range that corresponds to a predetermined range of phase shifts at the operational wavelength. Base designs are determined for a subset of the unit cells in each angular region of the metastructure design. After determining the base designs for the subset of the unit cells in a particular angular region, a respective design for each of one or more intermediate unit cells is interpolated based, at least in part, on the previously-determined base designs for the subset of unit cells that are in the same angular region as the one or more intermediate unit cells. A resulting metastructure design obtained based on the foregoing operations then can be used to manufacture one or more optical devices that include a metastructure based on the resulting metastructure design.

An apparatus in accordance with the present disclosure can include a device having an optical metastructure composed of unit cells, each of which has a respective unit cell design defined by a shape and area of meta-atoms for that unit cell, and by an arrangement of the meta-atoms within that unit cell. A first region of the metastructure comprises a plurality of adjacent unit cells that includes a subset of unit cells. The respective unit cell design for each of one or more of the plurality of unit cells that is in the first region, but that is not in the subset, is a respective interpolated unit cell design that is based on the respective unit cell designs of the unit cells in the subset.

Some implementations include one or more of the following features. For example, the adjacent unit cells in the first region can include a first endpoint unit cell, a second endpoint unit cell, and one or more intermediate unit cells disposed between the first and second endpoint unit cells, wherein the subset of unit cells in the first region consists of the first and second endpoint unit cells. In some cases, the first and second endpoint unit cells have a same topology as one another. In some instances, each of the intermediate unit cells in the first region has the same topology as the first and second endpoint unit cells.

In some implementations, the plurality of adjacent unit cells in the first region includes an inner unit cell, an outer unit cell, and one or more intermediate unit cells disposed between the inner and outer unit cells, wherein the inner unit cell is further from a periphery of the metastructure than is the inner unit cell, and wherein the subset of unit cells in the first region consists of the inner and outer unit cells. The inner and outer unit cells can have a same topology as one another. In some cases, each of the intermediate unit cells in the first region has the same topology as the inner and outer unit cells.

In some implementations, the respective unit cell design for each of the one or more of the plurality of unit cells that is in the first region, but that is not in the subset, is a respective image-morphed version based on the respective unit cell designs of the unit cells in the subset. In some instances, the subset of unit cells consists of two unit cells.

In some implementations, the plurality of adjacent unit cells are in a same angular region of the metastructure. In some cases, a lateral dimension of each unit cell in an angular direction is less than an operational wavelength λ for the metastructure.

In some implementations, a second region of the metastructure includes a second plurality of adjacent unit cells that includes a second subset of unit cells. In some instances, the respective unit cell design for each of one or more of the second plurality of unit cells that is in the second region, but that is not in the second subset, is a respective interpolated unit cell design that is based on the respective unit cell designs of the unit cells in the second subset. In some cases, the units cells in the first plurality of unit cells have a first topography, wherein the units cells in the second plurality of unit cells have a second topography, and wherein the second topography differs from the first topography.

The present disclosure also describes modules that include an optical device having a metastructure. The modules may include light emitting and/or light sensing components. The metastructure(s) may be disposed so as to intersect an emitted or incoming light wave and to modify one or more characteristics (e.g., phase, amplitude, angle, etc.) of the emitted or incoming light wave as it passes through the metastructure.

Other aspects, features and advantages will be apparent form the following detailed description, the accompanying drawings, and the claims.

### BRIEF DESCRIPTION OF THE DRAWINGS

FIG. 1 illustrates an example of an optical metastructure that includes unit cells.

FIG. 2 is a flow chart of a method of designing an optical metastructure.

FIG. 3 shows annular sections of the metastructure design.

FIGS. 4, 5 and 6 show examples of further operations in designing an optical metastructure.

FIG. 7 illustrates an example of a metastructure design in accordance with the techniques described in this disclosure.

FIG. 8 illustrates an example of a light sensing module including an optical device having one or more metastructures.

FIG. 9 illustrates an example of a light emitting module including an optical device having one or more metastructures.

### DETAILED DESCRIPTION

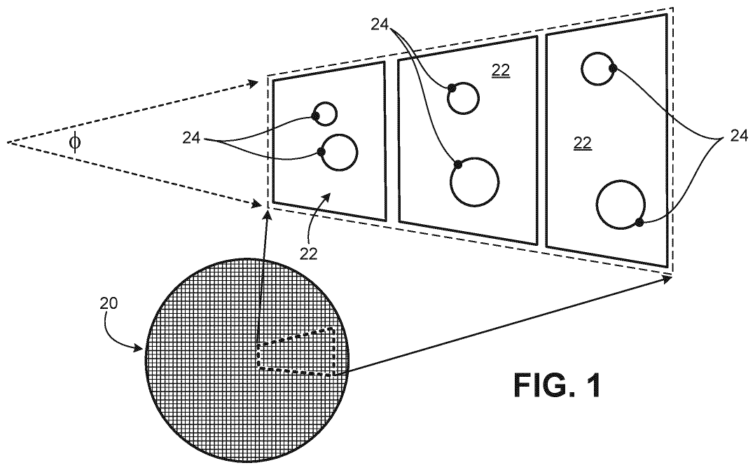

As shown in FIG. 1, an optical metastructure (e.g., a metalens) 20 may include many unit cells 22 having respective dimensions that differ from one another. Each unit cell 22 can include one or more meta-atoms 24. In general, a unit cell is defined by the shape of the unit cell, the area of the unit cell, and a corresponding base design. The base design of a unit cell can include the shape and area of the meta-atoms 24, as well as the arrangement of meta-atoms within the unit cell 22.

To optimize optical performance of the metastructure (e.g., a metalens), the unit cells should be customized according to their location within the metastructure. For example, in the case of a metalens, it may be desirable for unit cells near the periphery of a metalens to have a design that differs from the design of unit cells closer to the center of the metalens. The desirability of using different designs for the unit cells results, at least in part, because the unit cells have different dimensions in different parts of the metalens. On the other hand, determining different designs for numerous unit cells can be a complex, costly process.

The following paragraphs describe a method for obtaining the designs of unit cells of a metastructure. The method is applicable to unit cells that have a regular polygonal, annular or circular cross-section, as well as to arbitrarily-shaped (i.e., freeform) meta-atoms. Thus, the method can be used for meta-atoms having a non-circular cross-section, as well as meta-atoms having a circular cross-section (e.g., pillar-shaped meta-atoms). In some instances, the method can help reduce the overall complexity and/or design cost of the metastructure or improve its performance.

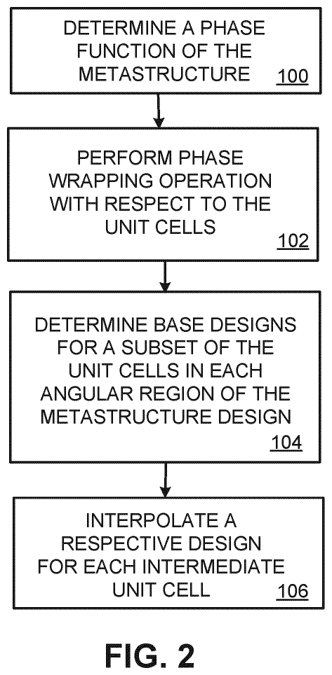

As indicated by 100 in FIG. 2, the method includes determining a phase function of the metastructure (e.g., a metalens) to produce a particular optical effect for a specified operational wavelength (λ). The phase function represents a target phase profile that specifies phase as a function of position for the metastructure.

As an example, a focusing lens that focuses at a focal length (f) for normal incidence may have a phase function ϕₗₑₙₛ, where:

$${ϕ}_{lens} = - 2 π / λ * ( sqrt ( {f}^{2} + {r}^{2} ) - f ) ,$$

and where r is the radial distance from the center of the lens. In this example, the radial dimension of a unit cell corresponds to the radial distance that represents a phase shift from one modulo-2π crossing to the next. Depending on the application, the operational wavelength may be, for example, in the infra-red (IR) or visible portion of the electromagnetic spectrum.

Although the drawings illustrate examples of round metastructures, more generally the metastructures may have any shape and need mot be circular with circular or annular subsections.

Next, as indicated by 102 (FIG. 2), a phase wrapping operation is performed with respect to the unit cells 22 such that the resulting radial dimension of each unit cell falls within a range that corresponds to a predetermined range of phase shifts at the operational wavelength λ. For example, in some implementations, the predetermined range of phase shifts is 0 to 4π. Thus, if the initial radial dimension of a particular unit cell 22 corresponds to a phase shift that falls outside the predetermined range, then the radial dimension is increased or decreased by an amount that corresponds to a phase change equal to an integer multiple of 2π such that the resulting radial dimension of the unit cell corresponds to a phase shift that falls within the predetermined range (e.g., within the range of 0 to 4π).

The phase function may be acquired in a way other than by the equation set forth above (e.g. numerical optimization or hand calculation). In such instances, the operations associated with 100 and 102 need not be performed explicitly.

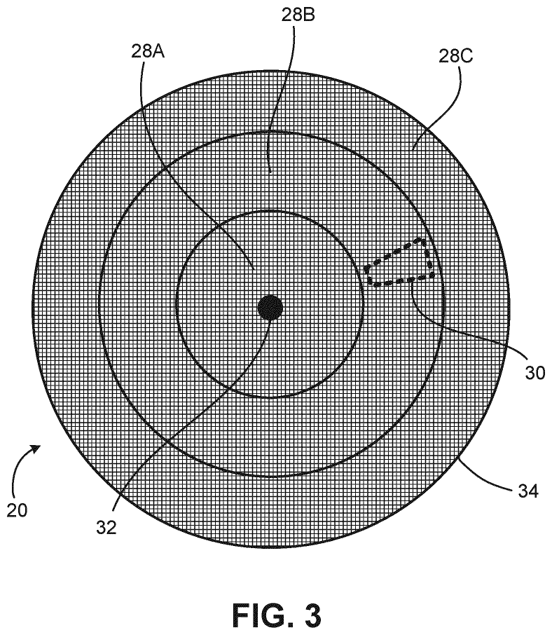

As shown in FIG. 3, the overall area for the metastructure design (e.g., of a lens) can be divided into multiple ring-shaped or annular sections, where each section is at a respective radial position. In the illustrated example, the annular section 28A is closest to the center 32 of the design, whereas the annular section 28C is furthest from the center 32 and closer to the periphery 34 of the design. Annular section 28B is an intermediate section, which is at a radial position between the inner section 28A and the outer section 28C. Thus, as shown in the simplified example of FIG. 3A, there are three annular sections 28A, 28B, 28C in the metastructure design. Typically, however, there may be tens or hundreds of different annular sections, each of which is located at a respective radial position. The radial width of each annular section 28A-28C may be based on the phase function itself (e.g., determined by conventional optical design). Thus, the radial width of each annular section 28A-28C can be larger than the operational wavelength, although it need not necessarily be a multiple of the operational wavelength. Each annular section 28A-28C may contain many unit cells along its respective radial direction. Further, the number of unit cells (e.g., along the radial direction) may differ from one annular section to the next.

Although the foregoing discussion assumes the lens has symmetric circular shape, this need not be the case. In some cases, for example, the lens may be elliptical.

The area of a unit cell 22 depends, in part, on an angle ϕ (see FIG. 1), which represents a percentage of the overall area covered by the metalens. The value of the angle ϕ is commonly selected such that there is an integer number of unit cell repetitions for the annular sections 28A through 28C in the metastructure, and such that the lateral dimension of each unit cell 22 in the angular direction is subwavelength (i.e., less than the operational wavelength λ), which can help avoid diffraction effects. In some implementations, the value of angle ϕ may vary from one section to another.

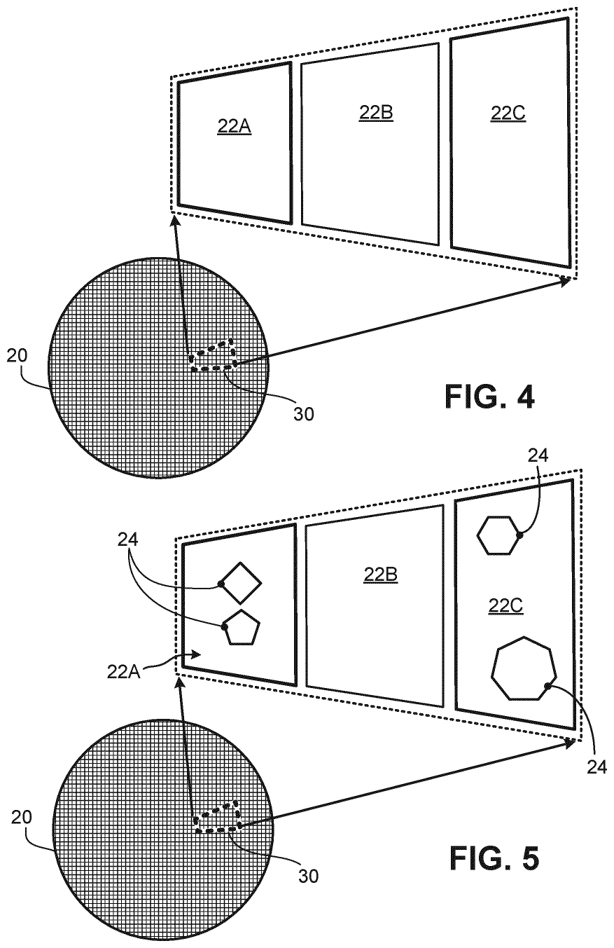

FIG. 4 illustrates a region 30 of the metastructure design including unit cells that are at the same angular position as one another within a particular one of the annular regions (e.g., annular region 28B). In the example of FIG. 4, the region 30 includes three unit cells 22A, 22B, 22C. The unit cell 22A, which is closest to the center of the metastructure design 20, may be referred to as an inner unit cell, and unit cell 22C, which is furthest from the center (i.e., closest to the periphery) of the metastructure design 20 may be referred to as an outer unit cell. Unit cell(s) such as unit cell 22B that are disposed between the inner and outer unit cells 22A, 22C may be referred to as intermediate unit cells. Although FIG. 4 shows the angular region 30 as having only three unit cells, typically there may be many intermediate unit cells within a given angular region 30.

As indicated by 104 (FIG. 2), after the phase wrapping operation is performed, base designs are determined for a subset of the unit cells 22 in each angular region 30 of the metastructure design. For example, in some implementations, a respective base design is determined for the inner unit cell 22A (i.e., the unit cell that is closest to the center of the design) and for the outer unit cell 22C (i.e., the unit cell that is furthest from the center, or closest to the periphery, of the design). During this stage of the process, a base design need not be determined for the other (i.e., intermediate) unit cells such as the unit cell 22B.

Determining the base design of a given unit cell 22 can include determining the shape and area of the meta-atoms 24 for that unit cell, as well as the arrangement of meta-atoms within the unit cell 22. As noted above, the meta-atoms 24 may have a polygonal, annular or circular cross-section, or an arbitrarily-shaped (i.e., freeform) cross-section. The base design for a particular unit cell 22 should approximate the phase-wrapped phase function for the corresponding part of the metastructure design. Preferably, the base design for the inner unit cell 22A and the base design for the outer unit cell 22C should have the same topology. FIG. 5 illustrates an example showing respective base designs for the inner and outer unit cells 22A, 22C having the same or similar topography as one another. Known techniques can be used to determine the base designs, including, for example, analytics, numerical simulations, and/or algorithms (gradient or non-gradient based approaches, or numerical optimization), some of which may employ direct design techniques that use maps relating the optical response of a unit cell to geometrical parameters of meta-atoms within it. Some techniques may employ, for example, spatial multiplexing and/or adjoint optimization.

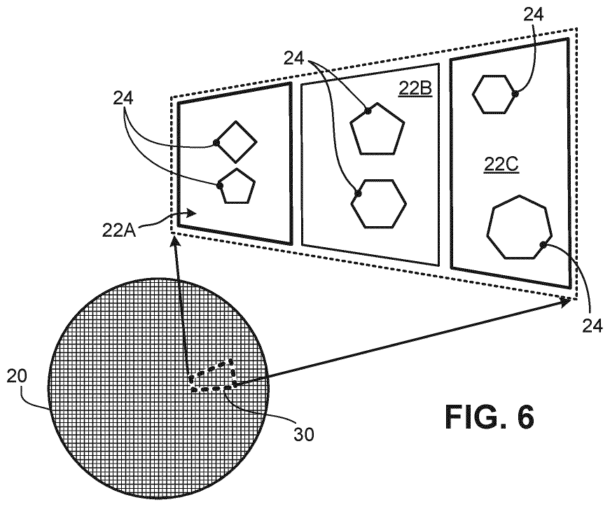

As indicated by 106 (FIG. 2), after determining the base designs for the subset of the unit cells 22 in each angular region 30, a respective design for each of the intermediate unit cell(s) 22B is interpolated based, at least in part, on the previously-determined base designs for the inner and outer unit cells 22A, 22C that are in the same angular region 30 as the particular intermediate unit cell. Determining the respective design for a given intermediate unit cell 22B can include determining a shape and area of the meta-atoms 24 for that intermediate unit cell, as well as an arrangement of meta-atoms within the intermediate unit cell. Here, as well, the design for a particular intermediate unit cell 22B should approximate the phase-wrapped phase function for the corresponding part of the metastructure design. FIG. 6 illustrates an example that shows an interpolated design for the intermediate unit cell 22B based on the previously-determined base designs for the inner and outer unit cells 22A, 22C.

In some implementations, the interpolation includes an image morphing operation. The image morphing operation preferably changes one unit cell design into another through a substantially seamless transition. In some implementations, the image morphing (which may sometimes be referred to shape morphing, shape blending or shape interpolation) may involve, for example, (piecewise-) affine or other general geometric transformations, as-rigid-as-possible shape interpolation, or interpolating splines and path/trajectory techniques. In some instances, the interpolating may include image processing techniques such as warping and/or cross dissolving, which allows one design to fade to another design using linear interpolation. Inputs for the interpolation operation can include, for example, details of the base unit cells 22A, 22C (e.g., the base design, location, and area of the base unit cells), as well as the area and location of the particular intermediate unit cell (e.g., unit cell 22B). As noted above, although FIGS. 4, 5 and 6 show only a single intermediate unit cell 22B between the inner and outer base unit cells 22A, 22C, there may be multiple intermediate unit cells between the base unit cells. The interpolation (e.g., image morphing operation) can be applied with respect to each of the intermediate unit cells in a particular angular region 30. The present technique can, in some cases, achieve a metastructure design in which there is a slowly varying transition from one unit cell to another in an optimized section 30 of the design.

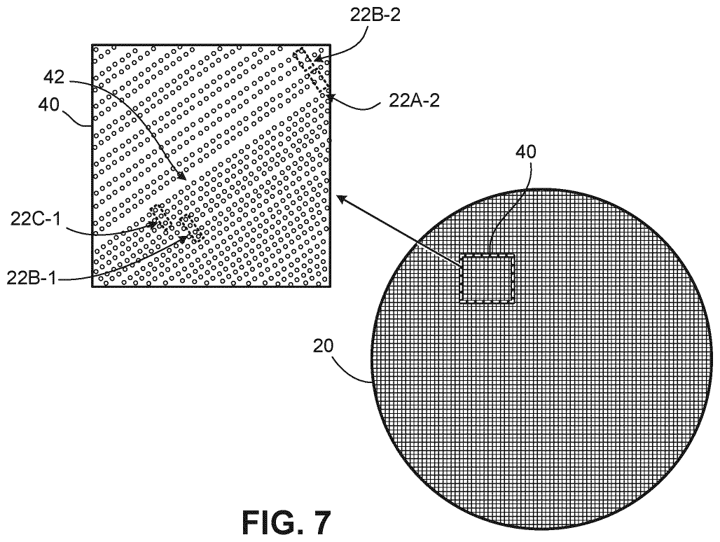

The foregoing operations, including determining base designs for a subset of the unit cells in a particular region 30 and then interpolating (e.g., by image morphing) a design for each respective intermediate unit cell in the same region 30, can be applied to multiple regions across the area for the metastructure design. In some cases, the foregoing operations can be applied, separately, to each angular region 30 in each of the annular regions 28A, 28B, 28C. An example is shown in FIG. 7, which shows an enlarged portion 40 of the overall metastructure design 20. The enlarged portion 40 shows a transition 42 between two optimized sections of the metastructure design, each of which has been optimized separately in accordance with the method of FIG. 2. FIG. 7 identifies an outer base unit cell 22C-1 and an interpolated intermediate unit cell 22B-1 in a first one of the sections, as well as an inner base unit cell 22A-2 and an interpolated intermediate unit cell 22B-2 in a second one of the sections. In the illustrated example, each of the unit cells 22B-1 and 22C-1 in the first section has three meta-atoms, whereas each of the unit cells 22A-2 and 22B-2 in the second section has two meta-atoms. That is, the topology of the first and second sections can differ from one another.

Once the design for each of the unit cells 22 is completed, the overall metastructure design can be used, for example, to manufacture optical devices. In some cases, a method of manufacturing the optical devices includes providing a substrate having a polymeric layer on a surface of the substrate, forming openings in the polymeric layer, and depositing a material in the openings to form meta-atoms based on the metastructure design. Adjacent ones of the meta-atoms may be separated from one another by polymeric material of the polymeric layer. In some instances, the openings in the polymeric layer are formed by an imprinting process. The imprinting process can include, for example, pressing a stamp into the polymeric layer, and the method can include hardening the polymeric material before separating the stamp from the polymeric layer. In some cases, the meta-material is deposited in the openings by atomic layer deposition. In some instances, the material deposited in the openings to form the meta-atoms is titanium dioxide, although other materials may be used for the meta-atoms in some implementations. In some implementations, some of the meta-atoms may be composed of a first material, whereas other meta-atoms are composed of a second, different material.

A metastructure made in accordance with the foregoing techniques can have features as described in connection with the metastructure design 20. Thus, for example, unit cells within a given optimized region can include one or more unit cells having a design (i.e., a shape and area of meta-atoms for that unit cell, as well as an arrangement of meta-atoms within the unit cell) that is derived from or otherwise based on a subset of the unit cells in the region. In particular, one or more intermediate unit cells can have a design that is an interpolated version of the respective design of two endpoint unit cells in the same region, where the intermediate unit cells are disposed between the two endpoint unit cells. In some instances, the endpoint unit cells are inner and outer unit cells, respectively, in the same region of the metastructure as the intermediate unit cells. As described above, the inner cell can be (relative to the outer unit cell) closer to the center of the metastructure and further from the periphery of the metastructure. Preferably, unit cells in a given optimized region of the metastructure have the same or very similar topography as one another. The present techniques can achieve, in some implementations, a metastructure that has a slowly varying transition from one unit cell to another within a given optimized region 30 of the metastructure.

Although the illustrated example in some of the foregoing figures is based on the metastrucutre being a metalens, the same or similar techniques can be used for other types of optical metastructures as well (e.g., lens arrays, beam splitters, diffusers, polarizers, bandpass filters, and other optical elements).

The foregoing optical devices can, in some cases, be fabricated using wafer-scale manufacturing processes, that is, using processes that allow tens, hundreds or even thousands of optical devices to be manufactured in parallel at the same time.

In some implementations, optical devices incorporating one or more metastructures as described above may be integrated into modules that house one or more optoelectronic devices (e.g., light emitting and/or light sensing devices). The metastructure can be used to modify one or more characteristics (e.g., phase, amplitude, angle, etc.) of an emitted or incoming light wave as it passes through the metastructure.

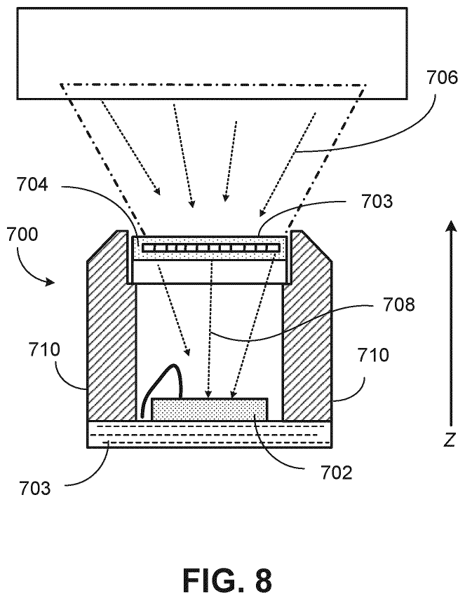

As shown, for example, in FIG. 8, in some implementations, a light sensing module (for example, an ambient light sensor module) 700 includes a light sensor (e.g., a photodiode, a pixel, or an image sensor) 702 mounted on a substrate 703. Light 706 incident on the module 700 is modified by a metastructure device 704, which may be implemented, for example, in accordance with a metastructure device as described above. In the single-channel module of FIG. 8, the metastructure device 704 is disposed so as to intersect a path of the incoming light 706. The metastructure device 704 can modify one or more characteristics of the light 706 impinging on the metastructure device before the light 708 is received and sensed by the light sensor 702. In some instances, for example, the metastructure device 704 may focus patterned light onto the light sensor 702. In some instances, the metastructure device 704 may split, diffuse and/or polarize the light 706 before it is received and sensed by the light sensor 702. The module housing may include, for example, spacers 710 separating the light sensor 702 and/or the substrate 703 from the metastructure device 704.

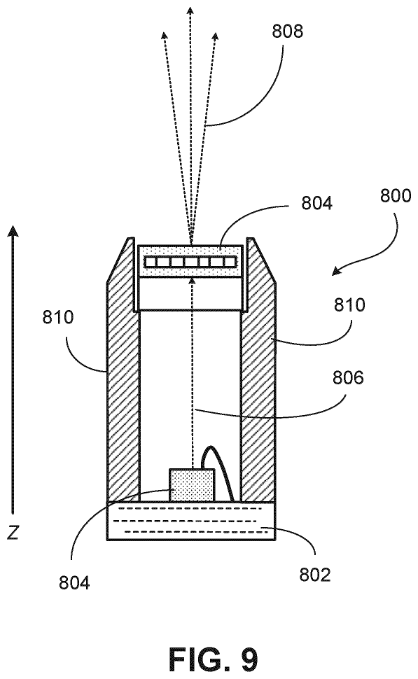

In some implementations, as shown in the example of FIG. 9, a module 800 includes a substrate 802 and a light emitter 804 mounted on, or integrated in, the substrate 802. The light emitter 804 may include, for example, a laser (e.g., a vertical-cavity surface-emitting laser) or a light emitting diode. Light 806 generated by the light emitter 804 passes through a metastructure device 804 and out of the module. The metastructure device 804 may be implemented, for example, in accordance with the techniques described above. In the single-channel module of FIG. 9, the metastructure device 804 is disposed so as to intersect a path of the outgoing light 806. The metastructure device 804 can modify one or more characteristics of the light 806 impinging on the metastructure before the light 808 exits the module 800. Thus, the metastructure device 804 is operable to modify the light 806, such that modified light 808 is transmitted out of the module 800. In some cases, the module 800 is operable to produce, for example, one or more of structured light, diffused light, and patterned light. The module housing may include, for example, spacers 810 separating the light emitter 804 and/or the substrate 802 from the metastructure device 804. In some instances, the module 800 is operable as a light generating module, e.g., as a structured light projector, a camera flash, a logo projecting module or as a lamp.

Multi-channel modules also can incorporate at least one metastructure device as described above. Such multi-channel modules can include, for example, a light sensor and a light emitter, both of which are mounted, for example, on the same printed circuit board (PCB) or other substrate. The multi-channel module can include a light emission channel and a light detection channel, which may be optically isolated from one another by a wall that forms part of the module housing.

In some instances, one or more of the modules described above may be integrated into mobile phones, laptops, televisions, wearable devices, or automotive vehicles.

Various aspects of the subject matter and the functional operations described in this specification (e.g., operations in the method of FIG. 2) can be implemented in digital electronic circuitry, or in computer software, firmware, or hardware, including the structures disclosed in this specification and their structural equivalents, or in combinations of one or more of them. Thus, aspects of the subject matter described in this specification can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The apparatus can include, in addition to hardware, code that creates an execution environment for the computer program in question, e.g., code that constitutes processor firmware.

Although particular implementations have been described in detail, various modifications can be made. Accordingly, other implementations are within the scope of the claims.

1. An apparatus comprising:
a device including an optical metastructure composed of unit cells, each of which has a respective unit cell design defined by a shape and area of meta-atoms for that unit cell, and by an arrangement of the meta-atoms within that unit cell,
wherein a first region of the metastructure comprises a plurality of adjacent unit cells that includes a subset of unit cells,
wherein the respective unit cell design for each of one or more of the plurality of unit cells that is in the first region, but that is not in the subset, is a respective interpolated unit cell design that is based on the respective unit cell designs of the unit cells in the subset.

2. The apparatus of claim 1 wherein the plurality of adjacent unit cells in the first region includes a first endpoint unit cell, a second endpoint unit cell, and one or more intermediate unit cells disposed between the first and second endpoint unit cells, and wherein the subset of unit cells in the first region consists of the first and second endpoint unit cells.

3. The apparatus of claim 2 wherein the first and second endpoint unit cells have a same topology as one another.

4. The apparatus of claim 3 wherein each of the intermediate unit cells in the first region has the same topology as the first and second endpoint unit cells.

5. The apparatus of claim 2 wherein the one or more intermediate unit cells includes multiple intermediate unit cells.

6. The apparatus of claim 1 wherein the plurality of adjacent unit cells in the first region includes an inner unit cell, an outer unit cell, and one or more intermediate unit cells disposed between the inner and outer unit cells, wherein the inner unit cell is further from a periphery of the metastructure than is the inner unit cell, and wherein the subset of unit cells in the first region consists of the inner and outer unit cells.

7. The apparatus of claim 6 wherein the inner and outer unit cells have a same topology as one another.

8. The apparatus of claim 7 wherein each of the intermediate unit cells in the first region has the same topology as the inner and outer unit cells.

9. The apparatus of any claim 6 wherein the one or more intermediate unit cells includes multiple intermediate unit cells.

10. The apparatus of claim 1 wherein the respective unit cell design for each of the one or more of the plurality of unit cells that is in the first region, but that is not in the subset, is a respective image-morphed version based on the respective unit cell designs of the unit cells in the subset.

11. The apparatus claim 1 wherein the subset of unit cells consists of two unit cells.

12. The apparatus of claim 1 wherein the plurality of adjacent unit cells are in a same angular region of the metastructure.

13. The apparatus of claim 12 wherein a lateral dimension of each unit cell in an angular direction is less than an operational wavelength λ for the metastructure.

14. The apparatus of claim 1 wherein a second region of the metastructure comprises a second plurality of adjacent unit cells that includes a second subset of unit cells,
wherein the respective unit cell design for each of one or more of the second plurality of unit cells that is in the second region, but that is not in the second subset, is a respective interpolated unit cell design that is based on the respective unit cell designs of the unit cells in the second subset.

15. The apparatus of claim 14 wherein the units cells in the first plurality of unit cells have a first topography, wherein the units cells in the second plurality of unit cells have a second topography, and wherein the second topography differs from the first topography.

16. A module comprising:
a light emitting component operable to emit incident light at an operational wavelength; and
an apparatus according to claim 1, wherein the light emitting component is mounted to direct the incident light to the metastructure.

17. The module of claim 16, wherein the light emitting component includes at least one of a light-emitting diode, a laser diode, or a vertical-cavity surface-emitting laser.

18. A module comprising:
a light-sensitive component operable to detect light; and
an apparatus according to claim 1, wherein the light-sensitive component is mounted to detect light passing through the metastructure into the module.

19. The module of claim 16 wherein the plurality of adjacent unit cells in the first region includes a first endpoint unit cell, a second endpoint unit cell, and one or more intermediate unit cells disposed between the first and second endpoint unit cells, and wherein the subset of unit cells in the first region consists of the first and second endpoint unit cells, wherein the first and second endpoint unit cells have a same topology as one another, and wherein each of the intermediate unit cells in the first region has the same topology as the first and second endpoint unit cells.

20. The module of claim 18 wherein the plurality of adjacent unit cells in the first region includes a first endpoint unit cell, a second endpoint unit cell, and one or more intermediate unit cells disposed between the first and second endpoint unit cells, and wherein the subset of unit cells in the first region consists of the first and second endpoint unit cells, wherein the first and second endpoint unit cells have a same topology as one another, and wherein each of the intermediate unit cells in the first region has the same topology as the first and second endpoint unit cells.
